(19) United States
(12) Patent Application Publication
(10) Pub. No.: US 2009/0032856 A1
(43) Pub. Date: Feb. 5, 2009

(54) MEMORY DEVICE AND MANUFACTURING METHOD THEREOF

(75) Inventors: Lee-Jen Chen, Taipei City (TW); Shian-Jyh Lin, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NANYA TECHNOLOGY CORPORATION, Taoyuan (TW)

(21) Appl. No.: 11/963,850

(22) Filed: Dec. 24, 2007

(30) Foreign Application Priority Data
Jul. 30, 2007 (TW) 96127758

(51) Int. Cl. H01L 27/108; H01L 21/8242

(52) U.S. Cl. 257/302; 438/241; 257/E27.092; 257/E21.654

(57) ABSTRACT

A manufacturing method of a volatile memory device is provided. The manufacturing method includes steps as follows. A sacrificial layer is formed in an area which is predetermined for forming a metal gate. Then, a thermal treatment process or other high temperature processes are performed in a peripheral circuit region. Next, a fabricating process of the metal gate is performed. Thus, the volatile memory device which has a lower contact resistance and a higher driving ability of the device can be produced, and thereby poor thermal stability and pollution of metal diffusion can be avoided.

### CROSS-REFERENCE TO RELATED APPLICATION

This application claims the priority benefit of Taiwan application serial no. 96127758, filed on Jul. 30, 2007. The entirety of the above-mentioned patent application is hereby incorporated by reference herein and made a part of this specification.

### BACKGROUND OF THE INVENTION

1. Field of the Invention

The present invention relates to an integrated circuit device and a fabricating method thereof. More particularly, the present invention relates to a memory device and a manufacturing method thereof.

2. Description of Related Art

Generally, in order to reduce the processing time and to simplify a fabricating process, a memory cell and a peripheral circuit are usually fabricated in a same process. Furthermore, according to different functions required by the devices, transistors with suitable functions are respectively formed in a memory cell region and a peripheral circuit region. For a dynamic random access memory (DRAM), the transistors can be classified into the transistors of the memory cell region and the transistors of the peripheral circuit region.

Currently, the transistors of the memory cell region of the DRAM are often fabricated by using a process of fabricating a recess channel instead of a process of forming a conventional stacked type gate structure, so as to increase a length of the channel, thereby reducing a short channel effect and preventing a leakage current problem.

A conventional fabricating process of the recess channel of the DRAM includes steps as follows. A substrate which has the memory cell region and the peripheral circuit region is provided at first. Next, a plurality of deep trench capacitors is formed in the substrate of the memory cell region. Then, a recess is in the substrate formed between adjacent deep trench capacitors. A source/drain region is formed at an upper part of the recess in the substrate. After that, a gate oxide layer is formed at sidewalls of the recess. Thereafter, a polysilicon layer which serves as a gate is filled into the recess for forming a transistor structure of the memory cell region. After the transistor of the memory cell region is completely fabricated, the gate of the transistor is defined, the source/drain region is implanted, and a high temperature activation process is performed in the peripheral circuit region.

As the level of the integration of a circuit gradually increases and devices are miniaturized continuously, due to the fact that a contact resistance is inversely proportional to a contact surface, the contact resistance is relatively increased in a miniaturized device, and thus affects a driving ability of the device. In solution, a metal material is usually used to replace polysilicon as the gate. However, the metal gate device usually has poor thermal stability problem and pollution of metal diffusion due to a thermal treatment process or other high temperature processes performed when fabricating the metal gate device.

Therefore, it has become one of the major goals in the development of the semiconductor industry to produce a high quality device that prevents the aforementioned problems.

### SUMMARY OF THE INVENTION

Accordingly, the present invention is directed to a memory device and a manufacturing method of the same, thereby preventing all kinds of problems derived from a conventional fabricating process and reducing a contact resistance for improving a driving ability of a device, so as to produce a high quality device.

The present invention provides a manufacturing method of a memory device. The manufacturing method includes steps as follows. First, a substrate which has a memory cell region and a peripheral circuit region is provided. A plurality of deep trench capacitors is disposed in the substrate of the memory cell region. An isolation structure is formed on each of the deep trench capacitors. Next, a recess is formed in the substrate between adjacent deep trench capacitors. Then, a source/drain region is formed in the substrate at an upper part of sidewalls of the recess. After that, a first gate dielectric layer is formed on the sidewalls of the recess. Thereafter, a first conductive layer is formed on the first gate dielectric layer. An upper surface of the first conductive layer is at a level lower than or equal to a bottom of the source/drain region. Afterwards, a dielectric layer is formed for compliantly covering the substrate. Then, a sacrificial layer is formed on the dielectric layer. An etching selectivity ratio of the sacrificial layer is different from that of the dielectric layer. After that, portions of the sacrificial layer are removed until exposing the dielectric layer. Then, the dielectric layer of the peripheral circuit region is removed. Next, a second gate dielectric layer and a second conductive layer are formed in sequence over the substrate of the peripheral circuit region. Then, the sacrificial layer and portions of the dielectric layer are removed until exposing the first conductive layer. After that, a metallic layer, a metal line layer and a hard mask layer are formed in sequence over the substrate. Next, a patterning process is performed for patterning the hard mask layer, the metal line layer, the metallic layer, the second conductive layer and the second gate dielectric layer, so as to form a first gate structure in the recess of the memory cell region and to form a second gate structure on the substrate of the peripheral circuit region.

According to the present embodiment, the manufacturing method of the memory device further comprises steps as follows. First, a first spacer and a second spacer are respectively formed at sidewalls of the first gate structure and sidewalls of the second gate structure. Next, an inner-layered dielectric layer is formed over the substrate. Then, a plurality of contact plugs is formed in the inner-layered dielectric layer for being electrically connected with the source/drain region of the memory cell region and the second gate structure of the peripheral circuit region respectively.

According to the manufacturing method of the memory device in an embodiment of the present invention, each of the deep trench capacitors comprises a lower electrode formed at a bottom of the deep trench in the substrate, a capacitor dielectric layer formed at sidewalls and the bottom of the deep trench, and an upper electrode formed on the capacitor dielectric layer.

According to the manufacturing method of the memory device in an embodiment of the present embodiment, each of the recesses is formed by steps as follows, for example. A spacer material layer is formed at first for compliantly covering the substrate and the isolation structure. Then, an anisotropic etching process is performed for removing portions of the spacer material layer, so as to form a spacer at sidewalls of the isolation structure. After that, the substrate is etched by using the spacer as an etching mask, and thereby the recess is formed.

According to the manufacturing method of the memory device in an embodiment of the present invention, the aforesaid source/drain region is, for example, formed by performing a tilted-angle ion implantation process.

According to the manufacturing method of the memory device in an embodiment of the present invention, the aforesaid first conductive layer is formed by steps as follows, for example. First, a conductive material layer is formed in the recess. Then, portions of the conductive material layer are removed until an upper surface of the conductive material layer is at a level lower then or equal to a bottom of the source/drain region.

According to the manufacturing method of the memory device in an embodiment of the present invention, the aforesaid dielectric layer is a silicon oxide layer fabricated by using tera-ethyl-ortho-silicate (TEOS) as a reactive gas source, for example. The aforesaid dielectric layer is formed by performing a chemical vapor deposition process, for example.

According to the manufacturing method of the memory device in an embodiment of the present invention, the aforesaid sacrificial layer is, for example, a conductive layer or a dielectric layer. The aforesaid conductive layer is, for example, a polysilicon layer. The aforesaid dielectric layer is, for example, a silicon nitride layer.

According to the manufacturing method of the memory device in an embodiment of the present invention, the portions of the sacrificial layer are removed until exposing the dielectric layer by performing an etching back process or a chemical-mechanical polishing process.

According to the manufacturing method of the memory device in an embodiment of the present invention, a material of the aforesaid metallic layer is, for example, titanium (Ti), titanium nitride (TiN), tantalum (Ta), tantalum nitride (TaN), hafnium nitride (HfN) molybdenum nitride (MoN), tungsten (W), platinum (Pt) or any other suitable material.

According to the manufacturing method of the memory device in an embodiment of the present invention, materials of the first conductive layer and the second conductive layer are, for example, doped polysilicon or other suitable materials.

The present invention further provides a memory device which includes a substrate, a recess channel type transistor and a stacked type transistor. The substrate has a memory cell region and a peripheral circuit region. A plurality of deep trench capacitors is disposed in the substrate of the memory cell region. A recess is disposed in the substrate between adjacent deep trench capacitors. The recess channel type transistor is disposed in the recess. A portion of the recess channel type transistor is disposed on the substrate. The recess channel type transistor includes a source/drain region disposed at an upper part of the recess in the substrate, and a first gate structure disposed in the recess. The first gate structure includes a first gate dielectric layer disposed at sidewalls of the recess, a first conductive layer disposed on the first gate dielectric layer at a bottom of the recess, a dielectric layer disposed on the first conductive layer at the sidewalls of the recess, a first metallic layer disposed on the first conductive layer, a first metal line layer disposed on the first metallic layer, and a first hard mask layer disposed on the first metal line layer. In addition, the stacked type transistor is disposed on the substrate of the peripheral circuit region. The stacked type transistor includes a second gate structure and is disposed on the substrate of the peripheral circuit region. The second gate structures includes, from the substrate, a second gate dielectric layer, a second conductive layer, a second metallic layer, a second metal line layer and a second hard mask layer.

According to an embodiment of the present invention, the memory device further includes a first spacer, a second spacer, an inner-layered dielectric layer and a plurality of contact plugs. The first spacer and the second spacer are respectively disposed at sidewalls of the first gate structure and at sidewalls of the second gate structure. The inner-layered dielectric layer is disposed over the substrate. The contact plugs are disposed in the inner-layered dielectric layer for being electrically connected with the source/drain region of the memory cell region and the second gate structure of the peripheral circuit region respectively.

According to an embodiment of the present invention, each of the deep trench capacitors includes a lower electrode disposed at a bottom of the deep trench in the substrate, a capacitor dielectric layer disposed at sidewalls and the bottom of the deep trench, and an upper electrode disposed on the capacitor dielectric layer.

According to an embodiment of the present invention, the aforesaid dielectric layer is a silicon oxide layer fabricated by using TEOS as a reactive gas source, for example.

According to an embodiment of the present invention, materials of the aforesaid first metallic layer and the aforesaid second metallic layer are, for example, titanium (Ti), titanium nitride (TiN), tantalum (Ta), tantalum nitride (TaN), hafnium nitride (HfN), molybdenum nitride (MoN), tungsten (W), platinum (Pt) or other suitable materials.

According to the memory device in the present embodiment, materials of the aforesaid first conductive layer and the aforesaid second conductive layer are, for example, doped polysilicon or other suitable materials.

According to the memory device of the present invention, the transistor of the memory cell region is the recess channel type transistor which can increase a length of the channel, so as to reduce a short channel effect and prevent a leakage current problem. Furthermore, the memory device of the present invention is a metal gate device which can reduce a contact electric resistance and improve a driving ability. In addition, according to the manufacturing method of the memory device in the present invention, the sacrificial layer is formed in an area which is predetermined to form a metal gate at first, next a thermal treatment process or any other suitable high temperature fabricating process is performed in the peripheral circuit region, and then a fabricating process for forming the metal gate is implemented. Therefore, a poor thermal stability problem and pollution of metal diffusion which are caused by the thermal treatment process or other high temperature processes in the fabricating process of the metal gate device can be avoided.

In order to the make the aforementioned and other objects, features and advantages of the present invention comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1I are schematic cross-sectional views illustrating a process flow for a manufacturing method of a volatile memory device according to one embodiment of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

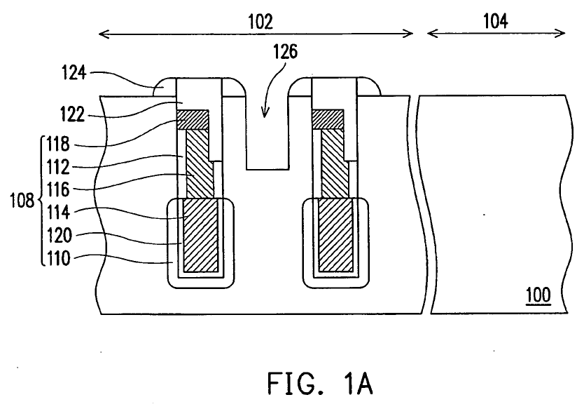

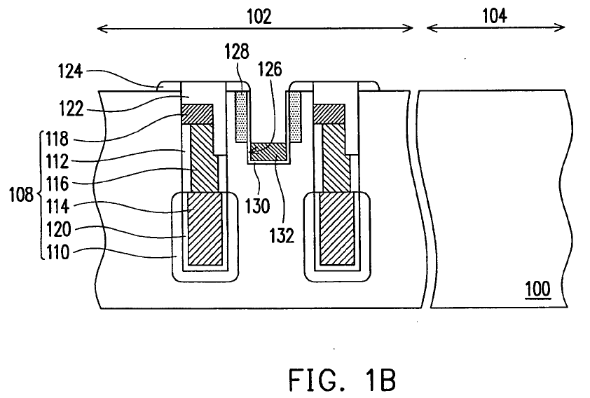

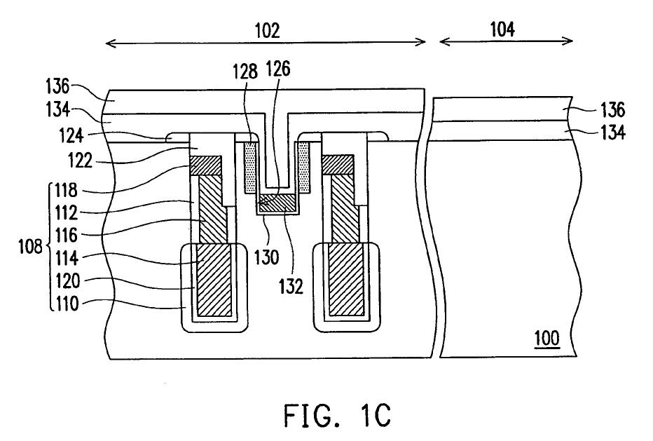

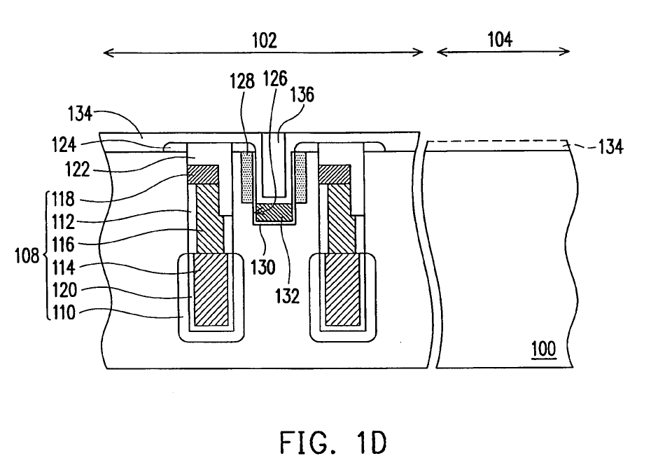

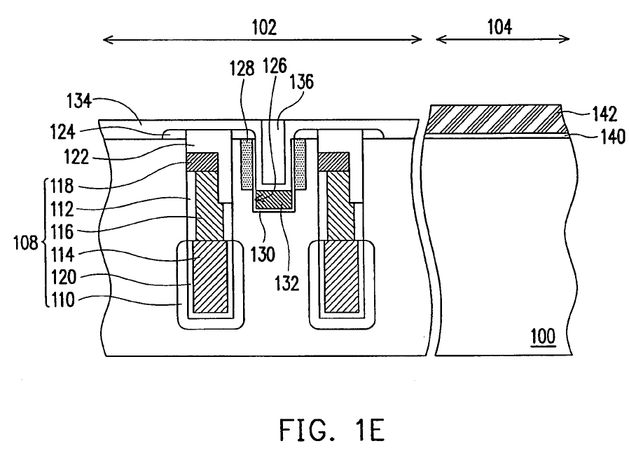

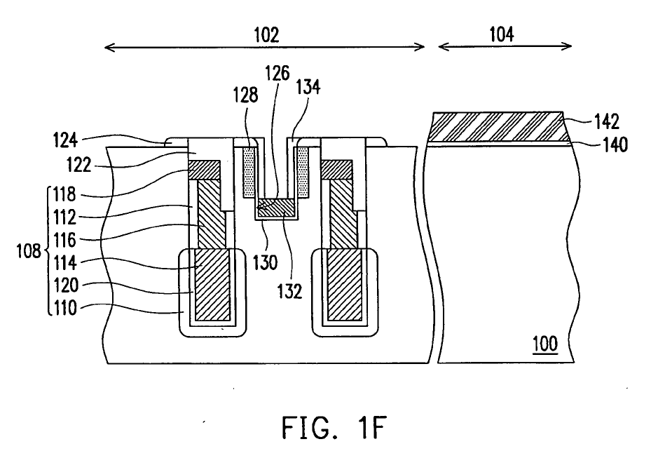

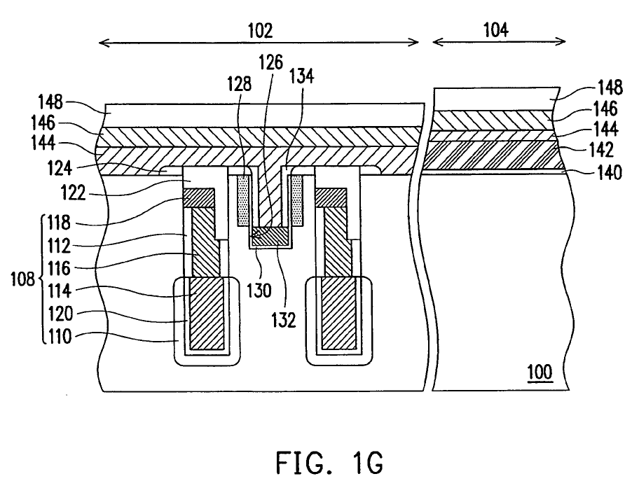

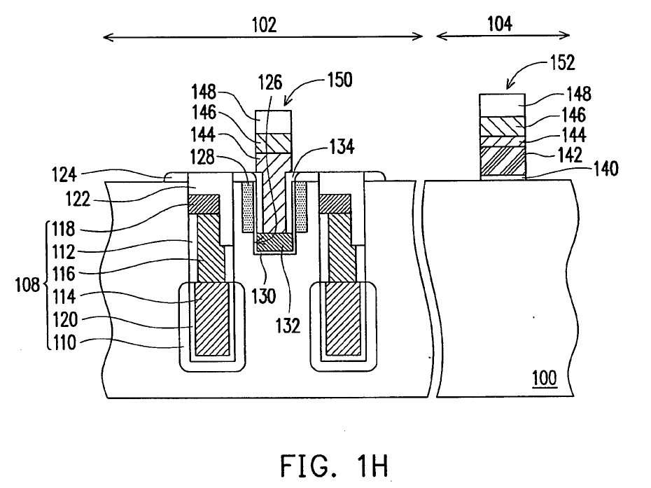

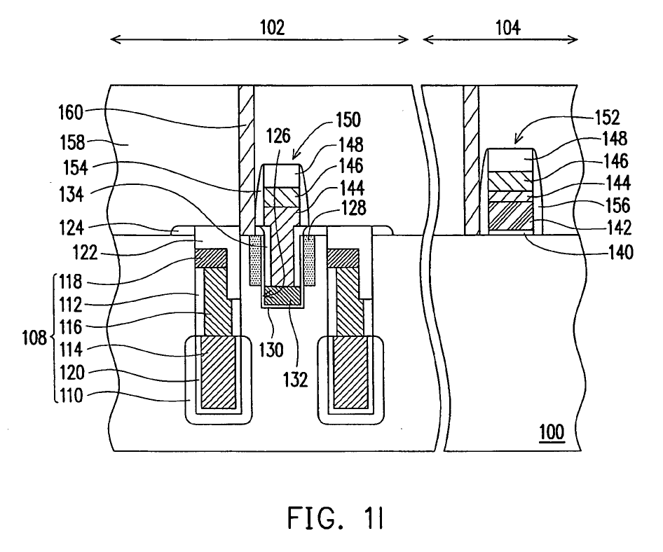

FIGS. 1A through 1I are schematic cross-sectional views illustrating a process flow for a manufacturing method of a volatile memory device according to one embodiment of the present invention.

First, referring to FIG. 1A, a substrate 100 is provided. The substrate 100 is, for example, a silicon substrate. The substrate 100 has a memory cell region 102 and a peripheral circuit region 104. A plurality of deep trench capacitors 108 is formed in the substrate 100 of the memory cell region 102. Each of the deep trench capacitors 108 comprises a lower electrode 110, a capacitor dielectric layer 120 and an upper electrode, for example. In the present embodiment, the upper electrode of each of the deep trench capacitors 108 is formed by conductive layers 114, 116 and 118. Materials of the conductive layers 114, 116 and 118 are, for example, doped polysilicon. The lower electrode 110 is, for example, a doped region. In addition, a collar oxide layer 112 can be formed between the conductive layer 116 and the substrate 100. A material of the collar oxide layer 112 is, for example, silicon oxide. A fabricating process of the deep trench capacitor 108 is well known to people skilled in the art, so the process is not described herein.

In the present embodiment, the upper electrode of each of the deep trench capacitors 108 is formed by three conductive layers 114, 116 and 118, which is considered as an example only. In fact, the upper electrode of each of the deep trench capacitors 108 can be formed by one conductive layer, two conductive layers, or even more than three conductive layers.

Then, an isolation structure 122 is formed on top of each of the deep trench capacitors 108. A material of the isolation structure 122 is silicon oxide, for example.

Next, referring to FIG. 1A, a recess 126 is formed in the substrate 100 between two adjacent deep trench capacitors 108. The recess 126 is formed by steps as follows, for example. A spacer material layer (not shown) is formed at first for compliantly covering the substrate 100 and the isolation structure 122. Then, an anisotropic etching process is performed for partially removing the spacer material layer, so as to form a spacer 124 at sidewalls of the isolation structure 122. Thereafter, the spacer 124 is used as an etching mask, and thereby the recess 126 is formed when etching the substrate 100. In one embodiment, the recess 126 has, for example, a rounded bottom for reducing a stress.

After that, referring to FIG. 1B, a source/drain region 128 is formed in the substrate 100 at an upper part of sidewalls of the recess 126. The source/drain region 128 is formed by performing a tilted-angle ion implantation process, for example. Afterwards, a gate dielectric layer 130 is formed on the inner surface of the recess 126. A material of the gate dielectric layer 130 is, for example, silicon oxide or any other suitable material. The gate dielectric layer 130 is formed by, for example, performing a thermal oxidation process.

Then, a conductive layer 132 is formed on the bottom of the recess 126. An upper surface of the conductive layer 132 is at a level lower than or equal to a bottom of the source/drain region 128. A material of the conductive layer 132 is doped polysilicon or any other suitable material. The conductive layer 132 is formed by steps as follows. A conductive material layer (not shown) is formed over the substrate 100 and fully filled in the recess 126 by performing a chemical vapor deposition process. Then, portions of the conductive material layer are removed by performing an etching back process for forming the conductive layer 132.

After that, referring to FIG. 1C, a dielectric layer 134 is formed for compliantly covering the substrate 100. The dielectric layer 134 is used for preventing the source/drain region 128 from being abnormally electrically connected with a subsequently formed gate. The dielectric layer 134 can be a silicon oxide layer fabricated by using tera-ethyl-ortho-silicate (TEOS) as a reactive gas source, for example. The dielectric layer 134 is formed by the chemical vapor deposition process, for example. Then, a sacrificial layer 136 is formed on the dielectric layer 134 and fully filled the recess 126 after the dielectric layer 134 is formed. An etching selectivity ratio of the sacrificial layer 136 is different from that of the dielectric layer 134. The sacrificial layer 136 is, for example, a conductive layer or a dielectric layer. A material of the conductive layer is, for example, polysilicon or any other suitable material. A material of the dielectric layer is, for example, silicon oxide or any other suitable material. At this time, the peripheral region 104 only has two layers on the substrate: the dielectric layer 134 and the sacrificial layer 136.

After that, referring to FIG. 1D, the etching back process or a chemical-mechanical polishing process is performed to partially remove the sacrificial layer 136 until an surface of the dielectric layer 134 is exposed. In the preceding steps, when the portions of the sacrificial layer 136 are removed, portions of the dielectric layer 134 are also removed, thereby the steps causing a decrease of a thickness of the dielectric layer 134. Thereafter, a photoresist layer (not shown) is formed on the memory cell region 102 and removing the dielectric layer 134 of the peripheral circuit region 104. Afterwards, the photoresist layer on the memory cell region 102 is removed.

It should be noted that according to the present embodiment, the sacrificial layer 136 is formed in an area which is predetermined to form a metal gate in the subsequent steps, thereby it could prevent a poor thermal stability problem and pollution of metal diffusion which are caused by the thermal treatment process or other high temperature processes performed when fabricating the metal gate device.

Next, referring to FIG. 1E, a gate dielectric layer 140 and a conductive layer 142 are sequentially formed on the substrate 100 of the peripheral circuit region 104. A material and a fabricating process of the gate dielectric layer 140 are, for example, the same as those of the gate dielectric layer 130, so the detailed description is not repeated. A material and a fabricating process of the conductive layer 142 are, for example, a conductive layer formed for covering the entire substrate 100. Then, a photoresist layer (not shown) is formed to cover the peripheral circuit region 104. After that, the conductive layer 142 of the memory cell region 102 is removed. In the present embodiment, the material of the conductive layer can be, for example, doped polysilicon. If the material of the sacrificial layer 136 is polysilicon as described above, the sacrificial layer 136 can be removed at the same time when removing the conductive layer of the memory cell region 102. After that, a dry etching process is performed, for example, and thereby portions of the dielectric layer 134 are removed until exposing the conductive layer. Finally, the photoresist layer of the peripheral circuit region 104 is removed and a structure is formed as shown in FIG. 1F.

Referring to FIG. 1G, a metallic layer 144 is formed over the substrate 100 and is filled into the recess 126. A material of the metallic layer 144 is, for example, titanium (Ti), titanium nitride (TiN), tantalum (Ta), tantalum nitride (TaN), hafnium nitride (HfN), molybdenum nitride (MoN), tungsten (W), platinum (Pt) or any other suitable metal material. The metallic layer 144 is formed by, for example, performing an atomic layer deposition process or any other suitable process. Then, a metal line layer 146 is formed on the metallic layer 144 for reducing an electric resistance. A material of the metal line layer 146 is, for example, tungsten silicide or any other suitable material. In the present embodiment, the metal line layer 146 of the memory cell region 102 and the peripheral circuit region 104 can be fabricated in the same process for reducing the processing cost, for example. Then, a hard mask layer 148 is formed on the metal line layer 146. A material for the hard mask layer 148 is, for example, silicon nitride or any other suitable material. The hard mask layer 148 is formed by performing the chemical vapor deposition process, for example.

Then, referring to FIG. 1H, a patterning process is performed for patterning the hard mask layer 148, the metal line layer 146, the metallic layer 144, the conductive layer 142, and the gate dielectric layer 140, so as to form a gate structure 150 in the recess 126 of the memory cell region 102, and to form a gate structure 152 on the substrate 100 of the peripheral circuit region 104. The aforesaid patterning process is, for example, a photolithographic process and the etching process.

It should be noted that according to the manufacturing method in the present embodiment, the sacrificial layer 136 is formed in the area which is predetermined to form the metal gate at first, next a thermal treatment process or any other suitable high temperature fabricating process is performed on the peripheral circuit region 104, and then a process of fabricating a metal gate is implemented. Therefore, the manufacturing method of the present embodiment does not have problems such as a poor thermal stability problem and pollution of the metal diffusion which occurs when fabricating a conventional metal gate device, and thus improving the device performance and the reliability of the fabricating process.

Next, referring to FIG. 1I, a spacer 154 and a spacer 156 are respectively formed at sidewalls of the gate structure 150 and at sidewalls of the gate structure 152. Materials of the spacer 154 and the spacer 156 are, for example, silicon nitride or any other suitable material. The spacer 154 and the spacer 156 are formed in the same process including following steps. A spacer material layer (not shown) is compliantly formed on the substrate 100. Then, an anisotropic etching process is formed for removing portions of the spacer material layer for forming the spacer 154 and the spacer 156.

After that, an inner-layered dielectric layer 158 is formed on the substrate 100. The inner-layered dielectric layer 158 is, for example, a low dielectric material layer for reducing the time delay of an interconnection. A material of the inner-layered dielectric layer 158 is, for example, potassium fluoride, fluorinated amorphous carbon, carbon doped oxide, parylene AF4, PAE, cyclotene or any other suitable low dielectric constant material. The inner-layered dielectric layer 158 is formed by, for example, the chemical vapor deposition process or any other suitable process.

Then, referring to FIG. 11, a plurality of contact plugs 160 is formed in the inner-layered dielectric layer 158 for being electrically connected with the source/drain region 128 of the memory cell region 102 and the gate structure 152 of the peripheral circuit region 104 respectively. The contact plugs 160 are formed by followings steps, for example. A plurality of contact holes exposing a bottom of the substrate is formed at first. Then, a polysilicon layer, a copper layer or any other suitable conductive material layer is filled into the contact holes for forming the contact plugs 160.

Next, please refer to FIG. 1I which illustrates a volatile memory device of the present invention formed by using the aforesaid method. Since the material and the manufacturing methods of each of the elements of the volatile memory device have been described above, so the detailed description is not repeated.

Further referring to FIG. 1I, the volatile memory device of the present invention includes the substrate 100, a recess channel type transistor and a stacked type transistor. Herein, the substrate 100 is, for example, a silicon substrate. The substrate 100 has the memory cell region 102 and the peripheral circuit region 104. A plurality of the deep trench capacitors 108 is formed in the substrate 100 of the memory cell region 102. The recess 126 is formed between adjacent deep trench capacitors 108 in the substrate 100. All of the elements of the deep trench capacitors 108 have been described above, so detailed description is not repeated.

The stacked type transistor, i.e. the gate structure 152, is disposed on the substrate 100 of the peripheral circuit region 104. The gate structure 152 includes, from the substrate 100, the gate dielectric layer 140, the conductive layer 142, the metallic layer 144, the metal line layer 146 and the hard mask layer 148.

The recess channel type transistor is disposed in the recess 126. A portion of the recess channel type transistor is disposed on the substrate 100 and is mainly constituted by the source/drain region 128 and the gate structure 150. The source/drain region 128 is disposed in the substrate 100 at the upper part of the recess 126. The gate structure 150 is disposed in the recess 126. The gate structure 150 comprises the gate dielectric layer 130 at the sidewalls of the recess 126, the conductive layer 132 on the gate dielectric layer 130 of the bottom of the recess 126, the dielectric layer 134 on the conductive layer 132 at the sidewalls of the recess 126, the metallic layer 144 disposed on the conductive layer 132, the metal line layer 146 disposed on the metallic layer 144, and the hard mask layer 148 disposed on the metal line layer 146.

Furthermore, the volatile memory device of the present invention further includes the spacer 154 and the spacer 156 which are respectively disposed at the sidewalls of the gate structure 150 and at the sidewalls of the gate structure 152. In one embodiment, an inner-layered dielectric layer 158 is disposed over the substrate 100. Furthermore, a plurality of contact plugs 160 is disposed in the inner-layered dielectric layer 158 for being electrically connected with the source/drain region 128 of the memory cell region 102 and the gate structure 152 of the peripheral circuit region 104 respectively.

In summary, the volatile memory device of the present invention and the manufacturing method thereof not only can form the metal gate structure for reducing the contact electric resistance and improving the driving ability of the devices, but also can prevent the poor thermal stability problem and the pollution of metal diffusion which are caused by the conventional metal gate device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A manufacturing method of a memory device, comprising:
providing a substrate having a memory cell region and a peripheral region, wherein a plurality of trench capacitors is disposed in the substrate of the memory cell region, and an isolation structure is formed on top of each of the trench capacitors;
forming a spacer on a sidewall of the isolation structure;
forming a recess in the substrate between two adjacent deep trench capacitors;
forming a source/drain region at an upper part of sidewalls of the recess in the substrate;
forming a first dielectric layer on the sidewalls of the recess;
forming a first conductive layer in a lower part of the recess;
forming an inner spacer along the first dielectric layer and above the conductive layer;
sequentially forming a second dielectric layer and a second conductive layer over the peripheral region of the substrate;
sequentially forming a metallic layer and a metal line layer on the substrate; and
patterning the metal line layer, the metallic layer, the second conductive layer and the second dielectric layer to form a first gate structure in the recess of the memory cell region and a second gate structure on the substrate of the peripheral region.

2. The manufacturing method of the memory device according to claim 1 further comprising:
forming a first spacer and a second spacer respectively on sidewalls of the first gate structure and sidewalls of the second gate structure;
forming an insulating layer over the substrate; and
forming a plurality of contact plugs in the insulating layer.

3. The manufacturing method of the memory device according to claim 1, wherein before the second gate dielectric layer forming step further comprises:
forming a sacrificial layer on the dielectric layer, wherein an etching selectivity ratio of the sacrificial layer is different from that of the dielectric layer;
removing portions of the sacrificial layer until exposing a surface of the dielectric layer; and
removing the dielectric layer of the peripheral region.

4. The manufacturing method of the memory device according to claim 3, wherein the recess forming step comprises:
forming a spacer material layer for compliantly covering the substrate and the isolation structure;
removing portions of the spacer material layer to form a spacer at sidewalls of the isolation structure; and
forming the recess by using the spacer as a hard mask.

5. The manufacturing method of the memory device according to claim 4, wherein a method for forming the source/drain region comprises performing a tilted-angle ion implantation process.

6. A memory device comprising:
a substrate having trench capacitors therein, and a gate structure formed between every two adjacent trench capacitors; and
an isolation structure formed on top of each of the at least two trench capacitors, wherein the isolation structure has a height higher than that of the substrate.

7. The memory device according to claim 6, wherein the isolation structure comprises a spacer formed on the substrate and on a sidewall of the isolation structure.

8. The memory device according to claim 7, wherein a portion of the gate structure is buried in the substrate.

9. The memory device according to claim 8 further comprising:
a gate spacer disposed at a sidewall of the gate structure;
an insulating layer disposed on the substrate; and
a contact plug disposed in the insulating layer to electrically connect to the substrate.
